(19) United States
(12) Patent Application Publication
(10) Pub. No.: US 2012/0104407 A1
(43) Pub. Date: May 3, 2012

(54) LIGHT EMITTING DIODE AND METHOD FOR MANUFACTURING THE SAME

(75) Inventors: TZU-CHIEN HUNG, Hukou Shiang (TW); CHIA-HUI SHEN, Hukou Shiang (TW)

(73) Assignee: ADVANCED OPTOELECTRONIC TECHNOLOGY, INC., Hsinchu Hsien (TW)

(21) Appl. No.: 13/172,734

(22) Filed: Jun. 29, 2011

(30) Foreign Application Priority Data
Oct. 29, 2010 (CN) 201010524075.1

(51) Int. Cl. H01L 33/22; H01L 33/32

(52) U.S. Cl. 257/76; 438/29; 257/E33.074; 257/E33.025

(57) ABSTRACT

An LED includes a substrate, a first n-type GaN layer, a connecting layer, a second n-type GaN layer, a light emitting layer, and a p-type GaN layer. The first n-type GaN layer is formed on the substrate, the first n-type GaN layer has a first surface facing away from the substrate, and the first surface includes a first area and a second area. The connecting layer, the second n-type GaN layer, the light emitting layer, and the p-type GaN layer are formed on the first area in sequence. The connecting layer is etchable by alkaline solution; a bottom surface of the second n-type GaN layer facing towards the connecting layer has a roughened exposed portion; the GaN on the bottom surface of the second n-type GaN layer is N-face GaN.

### BACKGROUND

1. Technical Field

The present disclosure relates to semiconductor devices and, particularly, to a light emitting diode and a method for manufacturing the light emitting diode.

2. Description of Related Art

Light emitting diodes (LEDs) have many beneficial characteristics, including low electrical power consumption, low heat generation, long lifetime, small volume, good impact resistance, fast response and excellent stability. These characteristics have enabled the LEDs to be used as a light source in electrical appliances and electronic devices.

In general, the light output of an LED depends on the quantum efficiency of the active layer and the light extraction efficiency. As the light extraction efficiency increases, the light output of the LED is enhanced. In order to improve the light extraction efficiency, efforts are made to overcome the significant photon loss resulting from total reflection inside the LED after emission from the active layer.

There are several methods for increasing the light extraction efficiency of the LED. A typical method for increasing the light extraction efficiency of the LED is to roughen the surface of the LED by etching the surface of the LED. However, it is difficult to roughen the surface of the conventional LED, and the etching process usually requires several hours; as a result, the efficiency of manufacturing the LED is decreased.

What is needed is an LED and a method for manufacturing the LED which can ameliorate the problem of the prior art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a cross-sectional view of an LED according to an exemplary embodiment.

FIG. 2 is a photo of an N-face GaN etched by alkaline solution.

FIGS. 3-8 are views each similar to that of FIG. 1, showing different steps of a process for manufacturing the LED according to the exemplary embodiment of FIG. 1.

### DETAILED DESCRIPTION

Embodiments of the present disclosure will now be described in detail below, with reference to the accompanying drawing.

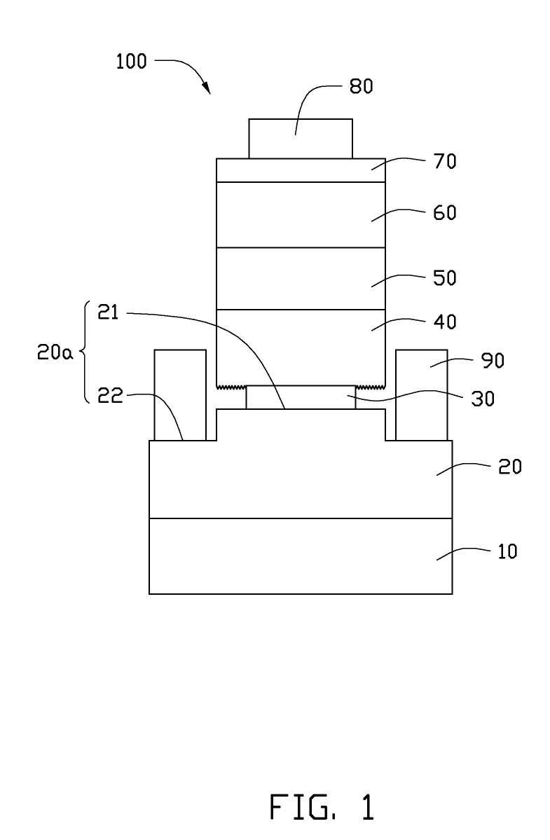

Referring to FIG. 1, an LED 100 according to an exemplary embodiment is shown. The LED 100 includes a substrate 10, a first n-type GaN layer 20, a connecting layer 30, a second n-type GaN layer 40, a light emitting layer 50, a p-type GaN layer 60, a transparent conductive layer 70, a p-type electrode 80, and an n-type electrode 90.

The substrate 10 can be made of a material selected from a group consisting of Si, SiC, and sapphire etc. In the present embodiment, the substrate 10 is made of sapphire.

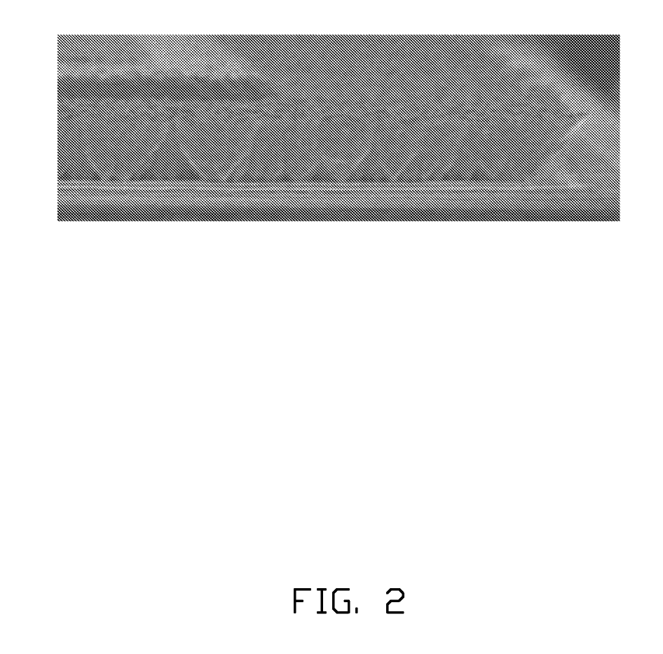

The first n-type GaN layer 20 is formed on the substrate 10, and has a first surface 20a facing away from the substrate 10. The first surface 20a includes a first area 21 and a second area 22. The connecting layer 30, the second n-type GaN layer 40, the light emitting layer 50, the p-type GaN layer 60, the transparent conductive layer 70, and the p-type electrode 80 are formed on the first area 21 in sequence. The n-type electrode 90 is formed on the second area 22. In the present embodiment, the second area 22 surrounds the first area 21, and the n-type electrode 90 is frame-shaped and surrounds the first area 21. The GaN on the first surface 20a of the first n-type GaN layer 20 is Ga-face GaN. Ga-face GaN has lattices thereof with Ga atoms on surfaces of the lattices. N-face GaN has lattices thereof with N atoms on surfaces of the lattices. N-face GaN can be etched by alkaline solution under 100 degree centigrade to form a roughened surface with hexagonal pyramid structures (see FIG. 2), but Ga-face GaN nearly does not react with alkaline solution under 100 degree centigrade.

The connecting layer 30 can be etched easily by alkaline solution under 100 degrees centigrade. The area of the connecting layer 30 is smaller than that of the second n-type GaN layer 40; thus, a bottom surface of the second n-type GaN layer 40 facing towards the connecting layer 30 has an exposed portion. The connecting layer 30 can be made of a material selected from a group consisting of AlN, SiO₂, and silicon nitride. In the present embodiment, the connecting layer 30 is made of AlN. Preferably, the thickness of the connecting layer 30 is in a range from 5 nm to 1000 nm.

The GaN on the bottom surface of the second n-type GaN layer 40 is N-face GaN. The exposed portion of the bottom surface of the second n-type GaN layer 40 is roughed to improve the light extraction efficiency of the LED 100.

The transparent conductive layer 70 can be made of Ni—Au alloy or Indium Tin Oxide (ITO). In the present embodiment, the transparent conductive layer 70 is made of ITO.

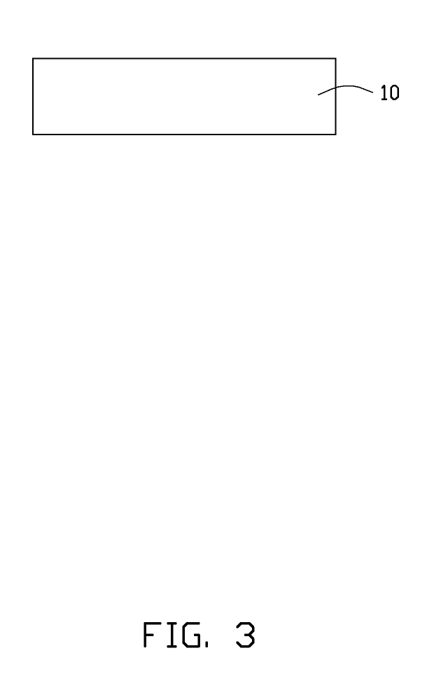

Referring to FIG. 3 to FIG. 8, a method for manufacturing the LED 100 according to the exemplary embodiment is shown. The method includes following steps.

Referring to FIG. 3, the first step is to provide a substrate 10. The substrate 10 can be made of a material selected from a group consisting of Si, SiC, and sapphire etc.

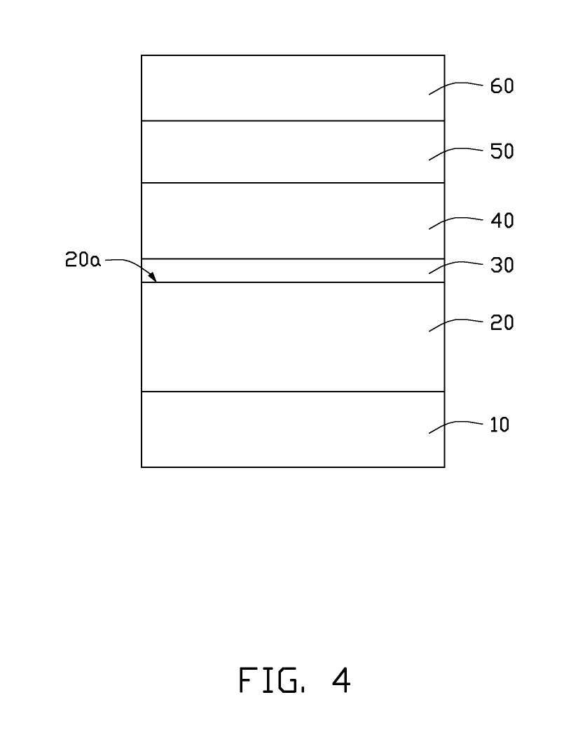

Referring to FIG. 4, the second step is to form the first n-type GaN layer 20, the connecting layer 30, the second n-type GaN layer 40, the light emitting layer 50, and the p-type GaN layer 60 on the substrate 10 in sequence. The GaN on the first surface 20a of the first n-type GaN layer 20 is Ga-face GaN, so that the first n-type GaN layer 20 would not be etched by alkaline solution. The connecting layer 30 can be etched easily by alkaline solution under 100 degree centigrade. The thickness of the connecting layer 30 is in a range from 5 nm to 1000 nm. The GaN on the bottom surface of the second n-type GaN layer 40 is N-face GaN which can be etched easily by alkaline solution.

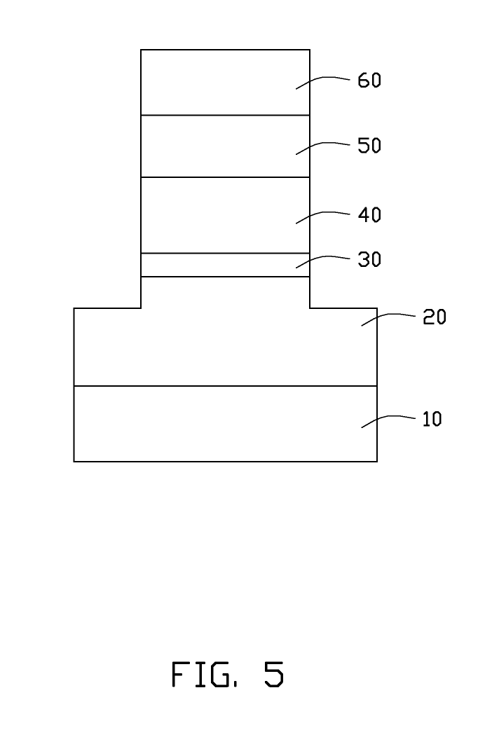

Referring to FIG. 5, the third step is to etch the p-type GaN layer 60, the light emitting layer 50, the second n-type GaN layer 40, and the connecting layer 30 to expose a portion of the first n-type GaN layer 20. The p-type GaN layer 60, the light emitting layer 50, the second n-type GaN layer 40, and the connecting layer 30 can be etched by using inductively coupled plasma technology. The first n-type GaN layer 20 can also has a portion being etched. In the present embodiment, the exposed portion of the first n-type GaN layer 20 surrounds the connecting layer 30.

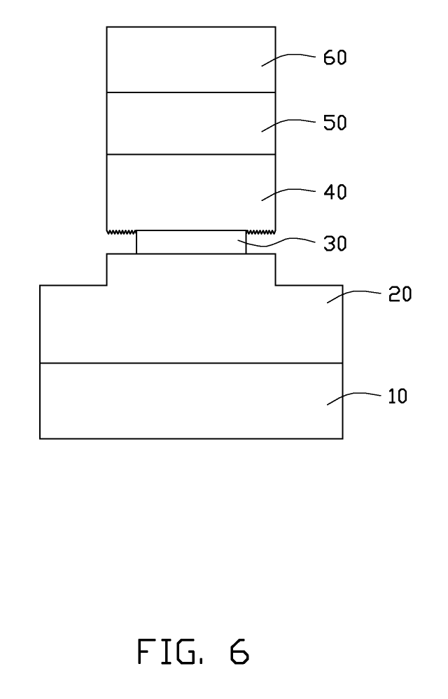

Referring to FIG. 6, the fourth step is to etch a portion of the connecting layer 30 by using alkaline solution to expose a portion of the bottom surface of the second n-type GaN layer 40, and etch the exposed portion of the bottom surface of the second n-type GaN layer 40 by using the alkaline solution to roughen the exposed portion of the bottom surface of the second n-type GaN layer 40. In order to accelerate the etching speed, the alkaline solution can be strong alkaline solution, such as KOH solution, NaOH solution etc.

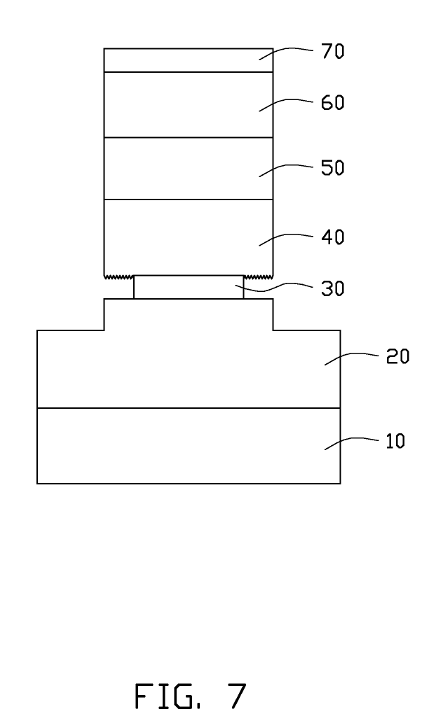

Referring to FIG. 7, the fifth step is to form the transparent conductive layer 70 on the p-type GaN layer 60.

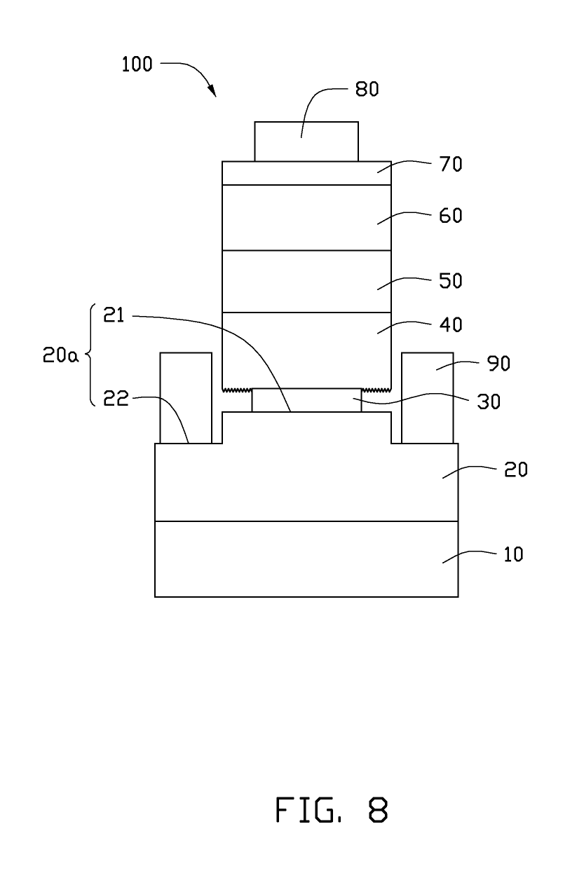

Referring to FIG. 8, the sixth step is to form the p-type electrode 80 on the transparent conductive layer 70, and to form the n-type electrode 90 on the exposed portion of the first n-type GaN layer 20. In the present embodiment, the n-type electrode 90 is frame-shaped and surrounds the connecting layer 30.

It should be understood that, the fourth step can also be arranged after the fifth step or the sixth step. In other embodiments, the fifth step to form the transparent conductive layer 70 can be omitted.

While certain embodiments have been described and exemplified above, various other embodiments will be apparent to those skilled in the art from the foregoing disclosure. The disclosure is not limited to the particular embodiments described and exemplified, and the embodiments are capable of considerable variation and modification without departure from the scope and spirit of the appended claims.

What is claimed is:

1. An LED comprising:
a substrate;
a first n-type GaN layer formed on the substrate, the first n-type GaN layer having a first surface facing away from the substrate, the first surface comprising a first area and a second area; and
a connecting layer, a second n-type GaN layer, a light emitting layer, and a p-type GaN layer formed on the first area of the first surface of the first n-type GaN layer in sequence, the connecting layer being etchable by alkaline solution, a bottom surface of the second n-type GaN layer facing towards the connecting layer having an roughed exposed portion, the GaN on the bottom surface of the second n-type GaN layer being N-face GaN.

2. The LED as claimed in claim 1, wherein a p-type electrode is formed on the p-type GaN layer, and an n-type electrode is formed on the second area of the first n-type GaN layer.

3. The LED as claimed in claim 2, wherein the second area of the first surface surrounds the first area of the first surface.

4. The LED as claimed in claim 3, wherein the n-type electrode is frame-shaped and surrounds the first area of the first surface.

5. The LED as claimed in claim 1, wherein a transparent conductive layer is disposed between the p-type electrode and the p-type GaN layer.

6. The LED as claimed in claim 1, wherein the GaN on the first surface of the first n-type GaN layer is Ga-face GaN.

7. The LED as claimed in claim 1, wherein the connecting layer is made of a material selected from a group consisting of AlN, SiO₂, and silicon nitride.

8. The LED as claimed in claim 1, wherein a thickness of the connecting layer is in a range from 5 nm to 1000 nm.

9. A method for manufacturing an LED comprising:
providing a substrate;
forming a first n-type GaN layer, a connecting layer, a second n-type GaN layer, a light emitting layer, and a p-type GaN layer on the substrate in sequence, the connecting layer being etchable by alkaline solution, the GaN on the bottom surface of the second n-type GaN layer being N-face GaN;
etching the p-type GaN layer, the light emitting layer, the second n-type GaN layer, and the connecting layer to expose a portion of the first n-type GaN layer; and
etching a portion of the connecting layer by using alkaline solution to expose a portion of the bottom surface of the second n-type GaN layer, and etching the exposed portion of the bottom surface of the second n-type GaN layer by using the alkaline solution to roughen the exposed portion of the bottom surface of the second n-type GaN layer.

10. The method as claimed in claim 9, further comprising a step of forming a p-type electrode on the p-type GaN layer, and forming an n-type electrode on the exposed portion of the first n-type GaN layer.

11. The method as claimed in claim 10, wherein the exposed portion of the first n-type GaN layer surrounds the connecting layer.

12. The method as claimed in claim 11, wherein the n-type electrode is frame-shaped and surrounds the connecting layer.

13. The method as claimed in claim 10, further comprising a step of forming a transparent conductive layer on the p-type GaN layer before forming the p-type electrode.

14. The method as claimed in claim 9, wherein the GaN on the first surface of the first n-type GaN layer is Ga-face GaN.

15. The method as claimed in claim 9, wherein the connecting layer is made of a material selected from a group consisting of AlN, SiO₂, and silicon nitride.

16. The method as claimed in claim 9, wherein a thickness of the connecting layer is in a range from 5 nm to 1000 nm.

17. The method as claimed in claim 9, wherein the alkaline solution is strong alkaline solution.

18. The method as claimed in claim 17, wherein the strong alkaline solution is KOH solution or NaOH solution.
